(19) United States
(12) Patent Application Publication
(10) Pub. No.: US 2016/0268610 A1
(43) Pub. Date: Sep. 15, 2016

(54) Multi-Layer Coating System for Corrosion Protection of Magnesium Cylinder Block Against Coolant

(71) Applicant: GM Global Technology Operations LLC, Detroit, MI (US)

(72) Inventors: Brian J. MCCLORY, Royal Oak, MI (US); Yucong WANG, West Bloomfield, MI (US); Mahmoud H. ABD ELHAMID, Troy, MI (US)

(21) Appl. No.: 14/643,449

(22) Filed: Mar. 10, 2015

(51) Int. Cl. H01M 8/02; C23C 28/04; C23C 16/08; C23C 18/16; C23C 16/44

(52) U.S. Cl. CPC H01M 8/02; C23C 18/1637; C23C 16/44; C23C 16/08; C23C 28/04

(57) ABSTRACT

A metallic part with improved corrosion resistance includes a metallic substrate that is coated with a metal fluoride layer. A primer layer is disposed over the metal fluoride layer. Finally, the metallic part is over-coated with a polymeric layer that is disposed over the primer layer.

### TECHNICAL FIELD

In at least one embodiment, the present invention provides methods and coatings for protecting metallic and metal alloy automotive components from corrosion.

### BACKGROUND

Metal corrosion is a ubiquitous problem that degrades the performance of many different automotive components. For example, corrosion tends to occur in various cooling systems such as those used for engine cooling, battery cooling and fuel cell cooling systems. Corrosion in automobile engine components is particularly undesirable because of the high associated costs of replacement and repair. In order to effectively minimize the effects of corrosion, it is often necessary to correctly identify the root cause.

Fluoride additions to automotive coolants have been shown to reduce corrosion in Mg materials. It is known that fluoride solutions can protect Mg alloys from corrosion by forming a protective layer on metals such as Mg. However, fluoride in the coolant is observed to corrode other metals in the cooling system.

Accordingly, there is a need for improvements in reducing corrosion in automotive parts.

### SUMMARY

The present invention solves one or more problems of the prior art by providing in at least one embodiment a metallic part with improved corrosion resistance. The metallic part includes a metallic substrate that is coated with a metal fluoride layer. A primer layer is disposed over the metal fluoride layer. Finally, the metallic part is over-coated with a polymeric layer that is disposed over the primer layer. The metallic part can be advantageously used in any application where metal corrosion occurs. Particularly useful applications include engine components and fuel cell components. If water penetrates both the polymeric layer (e.g., acrylic) and primer layer (e.g., oxide), the dissociation reaction of MgF₂ will be retarded by the top coating of the polymer layer. In this scenario, the concentration of HF that will form will be high, and will drive the reaction to re-form MgF₂ (i.e., the metallic part is self-healing).

In another embodiment, a method for forming the metallic part set forth above is provided. The method includes a step of forming a metal fluoride layer on a metallic substrate. The metal fluoride layer having a primer layer is then coated with a polymeric layer.

### BRIEF DESCRIPTION OF THE DRAWINGS

FIG. 1 is a schematic cross section of a metallic part with improved corrosion resistance; and

FIG. 2 is a schematic flowchart of a method for forming the metallic part of FIG. 1.

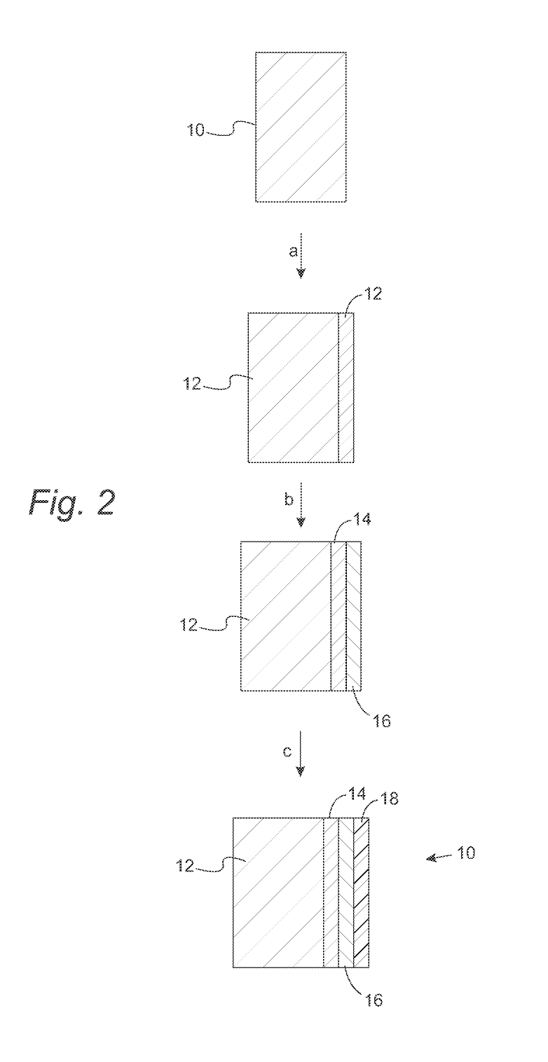

### DETAILED DESCRIPTION

Reference will now be made in detail to presently preferred compositions, embodiments and methods of the present invention which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

Throughout this application, where publications are referenced, the disclosures of these publications in their entireties are hereby incorporated by reference into this application to more fully describe the state of the art to which this invention pertains.

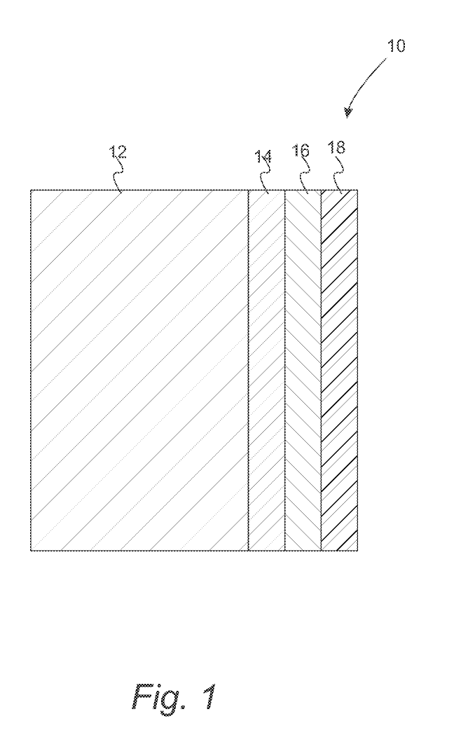

With reference to FIG. 1, a metallic part with improved corrosion resistance is provided. Metallic part 10 includes metallic substrate 12 that is coated with multiple layers. In particular, metal fluoride layer 14 is disposed over, and typically contacts, metal or metal alloy substrate 12. Primer layer 16 is disposed over, and typically contacts, metal fluoride layer 14. Finally, polymeric layer 18 is disposed over, and typically contacts, primer layer 16. The metallic part of the present embodiment is particularly useful when the metallic substrate is an automobile engine component or when the metallic substrate is positioned within an automobile engine block. The metallic part is also useful when the metallic substrate is a fuel cell component.

In a variation, metallic fluoride layer 14 has a thickness from about 1 micron to about 1 mm. In a refinement, metallic fluoride layer 14 has a thickness from about 2 microns to about 0.1 mm. In another variation, primer layer 16 has a thickness from about 5 microns to about 200 microns. In a refinement, primer layer 16 has a thickness from about 10 microns to about 100 microns. In still another variation, polymeric layer 18 has a thickness from about 500 microns to about 5 mm. In a refinement, polymeric layer 18 has a thickness from about 500 microns to about 1 mm.

A particularly useful metallic substrate is a magnesium alloy. Exemplary magnesium alloys include from 85 to 99 weight percent magnesium and 1 to 15 weight percent of a component selected from the group consisting of magnesium, aluminum, zinc, manganese, silicon, copper, rare earths and zirconium, yttrium, neodymium, silver, gadolinium, other rare earth metals, and combinations thereof.

Primer layer 16 can be virtually any layer that protects the integrity of metal fluoride layer 14 while allowing adhesion to polymer layer 18. In one variation, primer layer 16 is a metal oxide layer, metal nitride, metal carbide, metal boride, or a ceramic layer. In a refinement, primer layer 14 includes a component selected from silica oxide, magnesia, kaolin, montmorillonite, other clays, and combinations thereof. In another refinement, primer layer 14 includes an oxide of a metal selected from the group consisting of Al, Ca, Zn, Ca, Y, Si, Ti, and alloys thereof. In another variation, primer layer 14 is a metal layer or a metal alloy layer. Examples of useful alloys are Ni—P, Ni—P—Mo, Ni—Sn—P, Co—P, Co—P—Mo, Ni—B, Ni—B—Ti, Ni—B—Mo, Ni—B—Sn, Co—P, Co—P—W, Co—B, Ni—Cu—P, Cu, Zn, or combinations thereof.

As set forth above, metallic part 10 includes a metallic fluoride layer 14 which provides corrosion resistance to the metallic part Magnesium difluoride layer is found to be particularly useful, especially when the metallic substrate is magnesium or a magnesium-containing alloy.

As set forth above, metallic part 10 includes a polymer layer 18 which provides additional corrosion resistance and structural integrity. In one variation, polymer layer 18 is an acrylic layer. As used herein, an acrylic layer is a layer that includes or is an acrylic polymer or copolymer formed from monomers of acrylic acid and acrylic acid derivative. Examples of such monomers includes, but are not limited to, acrylic acid, methacrylates, methymethacrylate, methyl acrylate, ethyl acrylate, 2-chloroethyl vinyl ether, 2-ethylhexyl acrylate, hydroxyethyl methacrylate, butyl acrylate, butyl methacrylate, and combinations thereof.

In another embodiment, a method for forming the metallic part with improved corrosion resistance set forth above is provided. The details of the metallic part are set forth above in connection with the description of FIG. 1. In step a), metal fluoride layer 14 is formed on metallic substrate 12. In step b), metal fluoride layer 14 is coated with the primer layer 16. The primer layer can be formed by any a number of processes such as coating with an aqueous metal oxide-containing slurry, electroplating, electrolytic deposition, chemical vapor deposition, or electroless plating as set forth below in more detail. Typically, the metal fluoride layer is formed by contacting the metallic substrate with a fluorine containing compound. In step c), primer layer 16 is coated with polymeric layer 18.

### Fluoride Layer Formation

A metallic fluoride layer is formed on a metal substrate by exposing the substrate to a fluoride-containing acid solution, so that a chemical reaction occurs between the substrate and the solution. The substrate is either immersed in an acid bath, or an acid solution is passed over the surface of the substrate. The thickness of the metallic fluoride layer is controlled by regulating the process conditions under which the layer forms. Regulation of any or all the following variables is desired: substrate surface finish, acid solution concentration, acid solution temperature, exposure time. In particular, thicker layers are shown to form on surfaces which are rough rather than polished, using acid solutions that are of relatively higher concentration, at higher temperatures, and/or which are exposed to the substrate for longer durations of time. Such a process is used to develop a non-reactive MgF₂ layer on the surface of a magnesium alloy component, by immersing the component in a fluoride bath (e.g., HF or KF).

### Primer Layer Formation

Various processes can be used to develop the primer layer on top of the metallic fluoride substrate, including, but not limited to, slurry coating, electrolytic deposition, or electroless plating. For slurry coatings, a layer of ceramic primer coating is developed by applying an aqueous solution containing suspended particles of the desired metal oxide to the surface of the object to be coated, and allowing the slurry to dry. The suspended particle size and concentration in the aqueous solution are regulated to affect the end properties of the coating. Likewise, the final coating density and porosity content is influenced by controlling the amount of vacuum degassing of the slurry prior to its application on the part. In this manner, the properties of the primer layer can be varied to meet a range of requirements for coating strength and pore distribution throughout the layer. Multiple coating passes can be made if it is desired to vary coating properties through the thickness. For example, the primer might be denser and less porous at locations where it contacts the substrate. In these latter structures, the primer can transition to a more porous structure as distance from the substrate increases, to better accommodate the application and adhesion of subsequent acrylic coating layers.

With electrolytic deposition, the primer is developed on top of the substrate using electric current, an electrolyte solution which contains the cations for the element to be plated, and a sacrificial anode of the same metal to be plated or a noble counter electrode such as platinum or gold, while the cathode is the object onto which the primer is to be applied. Both anode and cathode are immersed in the electrolyte solution which contains the metallic salt and ions to provide electrical conductivity. The metallic ions from the solution electrodeposit on the magnesium substrate forming a metallic layer at a rate and hence a thickness that are controlled by regulating the applied current/voltage and duration of application. Alternatively, ceramic coatings such as f titania (TiO₂) could be electrodeposited in as a primer on top of an existing MgF₂ layer that was developed on the surface of a magnesium alloy component.

With electroless plating, no electrical energy source is required. Instead, the piece to be plated is placed in an aqueous solution containing metal ions and a reducing agent. The resulting reaction transfers metal from the solution onto the surface of the part. An example is electroless nickel plating, used to plate a nickel from an alloy such as Ni—P or Ni—B onto a substrate. The substrate is submerged in a solution containing a nickel source. A reducing agent such as sodium hypophosphite is added to the solution which, when heated, reacts with metal ions to allow the deposit of nickel onto the part surface. The amount of nickel deposited is regulated by using additives in the solution. Different additives are used to control the amount of free nickel available to be deposited, to accelerate or slow the reaction rate, and to resist pH changes in the solution which occur as the reaction proceeds. The resultant coating physically protects the substrate below it and provides additional corrosion protection, yet can also act as a base primer for additional layers of protective coating to be applied above if desired.

### Formation of Acrylic Layer

An acrylic layer is used as the top coating in a multi-layer coating system to act as a physical barrier which protects the layers below it from damage. It is a conformal coating which readily bonds to the porous underlayment onto which it is applied. Application of the coating is accomplished by various methods including, but not limited to, brushing, dipping spraying, and physical or chemical vapor deposition. The bulk geometry of the substrate dictates which method is indicated, with line-of-sight being necessary for many processes, while a process such as chemical vapor deposition (CVD) is used for reaching hidden surfaces that define internal passages and the like.

When used in a multi-layer corrosion protection system, the acrylic protects the underlying layers from physical damage and exposure to corrosive elements. Should the acrylic and underlying layers be damaged, however, the acrylic also acts to minimize the resulting corrosion. For the case of a coated magnesium alloy, if water penetrates both the acrylic and primer layers to reach the protective MgF₂ layer, the dissociation reaction of MgF₂ is retarded by the presence of the acrylic. The concentration of HF that forms when the dissociation reaction begins is high, and drives the reaction to re-form MgF₂, just as occurred in the original creation of the MgF₂ layer. That is to say, the presence of the top layer of acrylic means that the multi-layer system can be self-healing.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A metallic part with improved corrosion resistance, the metallic part comprising:
a metallic substrate;
a metal fluoride layer disposed over the metal or metal alloy substrate;
a primer layer disposed over the metal fluoride layer; and
a polymeric layer disposed over the primer layer.

2. The metallic part of claim 1 wherein the metallic fluoride layer has a thickness from about 1 micron to about 1 mm and the primer layer has a thickness from about 5 microns to about 200 microns.

3. The metallic part of claim 1 wherein the polymeric layer has a thickness from about 500 microns to about 5 mm.

4. The metallic part of claim 1 wherein the metallic substrate is a magnesium alloy.

5. The metallic part of claim 4 wherein the magnesium alloy includes from 85 to 99 weight percent magnesium and 1 to 15 weight percent of a component selected from the group consisting of magnesium, aluminum, zinc, manganese, silicon, copper, rare earths and zirconium, yttrium, neodymium, silver, gadolinium, other rare earth metals, and combinations thereof.

6. The metallic part of claim 1 wherein the primer layer is a metal oxide layer, metal nitride, metal carbide, metal boride, or a ceramic layer.

7. The metallic part of claim 1 wherein the primer layer includes silica oxide, magnesia, kaolin, montmorillonite, other clays, and combinations thereof.

8. The metallic part of claim 1 wherein the primer layer includes an oxide of a metal selected from the group consisting of Al, Ca, Zn, Ca, Y, Si, Ti, and alloys thereof.

9. The metallic part of claim 1 wherein the primer layer is a metal layer or a metal alloy layer.

10. The metallic part of claim 9 wherein the primer layer includes an alloy selected from the group consisting of an alloy Ni—P, Ni—P—Mo, Ni—Sn—P, Co—P, Co—P—Mo, Ni—B, Ni—B—Ti, Ni—B—Mo, Ni—B—Sn, Co—P, Co—P—W, Co—B, Ni—Cu—P, Cu, Zn, and combinations thereof.

11. The metallic part of claim 1 wherein the metal fluoride layer is a magnesium difluoride layer.

12. The metallic part of claim 1 wherein the polymer layer is an acrylic layer.

13. The metallic part of claim 1 wherein the metallic substrate is positioned within an automobile engine block.

14. The metallic part of claim 1 wherein the metallic substrate is an automobile engine component.

15. The metallic part of claim 1 wherein the metallic substrate is a fuel cell component.

16. A method for forming a metallic part with improved corrosion resistance, the metallic part including a metallic substrate, a metal fluoride layer disposed over the metal or metal alloy substrate, a primer layer disposed over the metal fluoride layer, and a polymeric layer disposed over the primer layer, the method comprising:
forming the metal fluoride layer on the metallic substrate;
coating the metal fluoride layer with the primer layer; and
coating the primer layer with the polymeric layer.

17. The method of claim 16 wherein the metal fluoride layer is formed by contacting the metallic substrate with a fluorine containing compound.

18. The method of claim 16 wherein the primer layer is formed by, electrolytic deposition, chemical vapor deposition, or electroless plating

19. The method of claim 16 wherein the primer layer is formed from an aqueous metal oxide-containing slurry.
